(19) United States
(12) Patent Application Publication
(10) Pub. No.: US 2001/0045839 A1
(43) Pub. Date: Nov. 29, 2001

(54) Verification of PWB electrical parameters

(76) Inventors: Richard St-Onge, Ile Bizard (CA); Yves DeFlandre, Pierrefond (CA)

Correspondence Address: Gary S. Engelson,, Wolf, Greenfield & Sacks, P.C., 600 Atlantic Avenue, Boston, MA, 02210, US

(21) Appl. No.: 09/775,883

(22) Filed: Feb. 2, 2001

Related U.S. Application Data
(60) Provisional application No. 60/179,763, filed on Feb. 2, 2000.

(51) Int. Cl. G01R 31/02

(52) U.S. Cl. 324/758

(57) ABSTRACT

A capacitor and an optical alignment pattern are provided on a printed wiring board (PWB) to permit a quick verification of electrical parameters, thereof. A method of verifying electrical parameters of a PWB measures a capacitance and optical alignment, without measuring performance by a circuit formed on the PWB.

### BACKGROUND

1. Cross Reference to Related Application

This application claims domestic priority under 35 U.S.C. §119 (e) to U.S. Provisional patent application Ser. No. 60/179,763, filed Feb. 2, 2000.

2. Field of the Invention

The present invention relates to structures and methods for verifying the electrical characteristics of printed wiring boards.

3. Related Art

One popular class of connectivity products electrically adapt, compensate or match standard connectors, such as RJ-45 style connectors, to insulation displacement connectors (IDCs). Herein, adaptation, compensation or matching refers to providing electrical parameters in one component of a system which cooperatively interacts with the electrical parameters of another component of the system to provide a desired performance characteristic or other parametric characteristic. One example of adaptation, compensation or matching is simple impedance matching. More complex matching functions are also possible. Adaptation, compensation or matching increases the communication bandwidth of which a connector system is capable. To achieve higher transmission performance, various kinds of electrical coupling between conductors of the connector system are required, including both inductive and capacitive coupling. The precision with which such coupling can be defined in real systems directly affects system performance.

A practical way to adapt RJ-45 style connectors to IDC connectors is by using printed wiring board (PWB) technologies. The structure of the conductive traces of a PWB can define the compensation components needed, for example, capacitors and inductors. As performance requirements are made more stringent, parameters such as the positioning and size of the conductive traces of the PWB which comprise the compensation components must be made more precise. Thus, PWB fabrication tolerances need to be more precise and stable to produce the required compensation components.

Although it is possible to improve the tolerance to which PWBs are manufactured to a desired level, doing so increases the cost of the PWB drastically. Also, conventional methods used to evaluate each supplier lot of PWBs are costly. For example, board quality cannot be determined by directly measuring circuit elements comprising compensation circuits which are constructed of conductive traces on the PWB because the structures are excessively complex. Thus, tolerances of PWB based circuits presently vary unacceptably from batch to batch.

### SUMMARY OF THE INVENTION

1. A test structure for a printed wiring board (PWB), comprising at least one of:

a plurality of conductive traces disposed on separate layers of the PWB and superposed to form a capacitor, separate from any circuit formed on the PWB, and

a plurality of conductive traces dissposed on separate layers of the PWB which are aligned when the separate layers of the PWB are properly aligned.

2. A method of testing a printing wiring board (PWB), comprising steps of:

measuring capacitance of a capacitor formed by traces on the PWB, the capacitor independent of any circuit on the PWB; and

comparing visual alignment of plural traces discrete from any circuit on the PWB to an acceptance criteria.

3. In a printed wiring board (PWB), including at least one substantially reactive circuit element formed of conductive traces on plural layers thereof, a test structure comprising at least one of:

a capacitor including conductive traces on plural layers thereof, the capacitor independent of any circuit on the PWB; and

an inductive test structure including conductive traces on plural layers thereof whole alignment is detectable optically by an unaided observer.

### BRIEF DESCRIPTION OF THE DRAWINGS

In the drawings in which like reference designations indicate like elements.

FIG. 1 is a plan view of a “T” design capacitive test structure embodying aspects of the invention;

FIG. 2 is a plan view of an “M” design capacitive test structure embodying aspects of the invention;

FIG. 3 is a plan view of one inductive test structure embodying aspects of the invention; and

FIG. 4 is a plan view of another inductive test structure embodying aspect of the invention.

### DETAILED DESCRIPTION OF EMBODIMENTS OF THE INVENTION

Embodiments of the invention can be used to measure printed wiring board (PWB) lot quality and also can be used to certify whether a finished product will or will not meet transmission performance. The inventors have found that by adding one or more, preferrably two reference components to a PWB, expected performance can be predicted. This prediction may be used either during a PWB development process, to help define the fabrication requirements, or during PWB production, for quality control inspection. Parameters useful to measure include those which would affect the values of capacitors and the values of inductors formed by the conductive traces of the PWB. For that purpose, two reference components, called a capacitive test structure and an inductive test structure respectively, are incorporated in the PWB conductive traces.

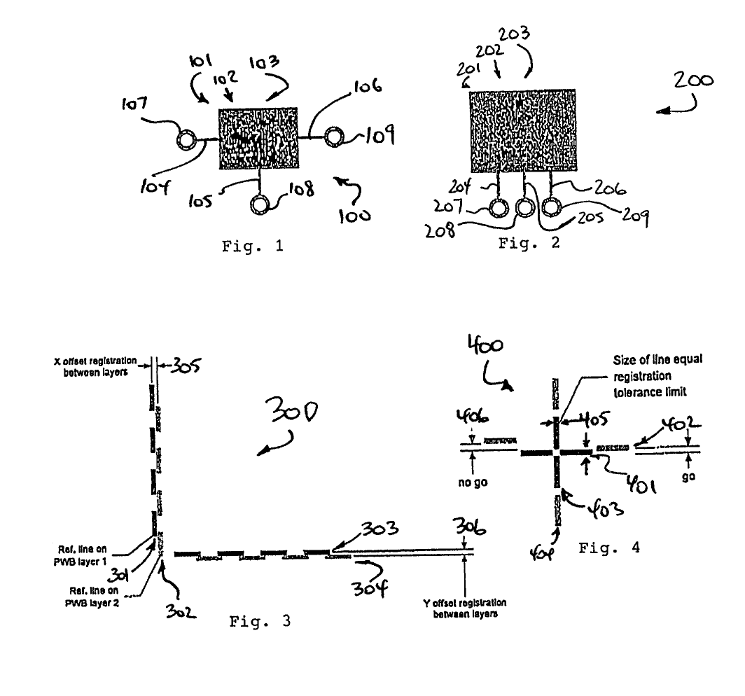

The capability of the PWB fabrication process to make accurate capacitive structures is measured by adding capacitive coupling test structures at one or more locations on the PWB. See FIGS. 1 and 2, for example. Locating two conductive surfaces in close proximity creates a capacitor. The capacitor value depends on 3 factors:

Area over which the plates are proximate or overlapping;

Distance between the plates; and

Dielectric constant of the material between plates.

Capacitive test structures having the form of reference capacitors as shown in FIGS. 1 and 2 can give an indication in a single, composite parameter of the manufacturing variation of board thickness and etch placement accuracy obtained by the PWB manufacturer. Each plate of such reference capacitors should be located on the same layers of the PWB as are plates of similar capacitors embedded in circuits used for compensation. Therefore, any variation of one or more of the three factors will change the measured capacitance of the capacitive test structure. In addition, any variation in the alignment of the layers, i.e., registration, produces measurable changes to the capacitance of the capacitive coupling test structure. The measured values of capacitance of the structure predict product performance. Because only one parameter, capacitance, is measured to provide an indication of the accuracy of several parameters, dielectric thickness, plate size and plate registration, particular problems are not identified. However, a quick PWB acceptance test is possible based on the single measurement. Such a test can be used in design or production, as described below.

FIG. 1 shows a plan view of one capacitive test structure having the form of reference capacitor having a “T” design. FIG. 2 shows a plan view of another capacitive test structure having the form of a reference capacitor having an “M” design. The “T” design is presently preferred because it exhibits less parasitic reactance than the “M” design, permitting more precise measurements using smaller values, which in turn use less PWB space. The capacitance of capacitive test structures in the form of reference capacitors is measured directly by connecting a reactance measuring device to the exposed terminals.

The capacitive test structure 100 of FIG. 1 includes three separate plates, 101, 102 and 103, separated from each other by dielectric material comprising the substrate of a PWB. Each plate 101, 102 and 103 has connected thereto a respective conductive trace 104, 105 and 106, connected to a respective via 107, 108 and 109, at which contact can be made by a test instrument. In this “T” design embodiment, traces 104, 105 and 106 are aligned in a generally “T” shape, thereby minimizing reactance between them.

The capacitive test structure 200 of FIG. 2 also include three separate plates 201, 202 and 203, separated from each other by dielectric material comprising the substrate of a PWB. As in the structure 100, each plate 201, 202 and 203 of structure 200 has connected thereto a respective conductive trace 204, 205 and 206, corrected to a respective via 207, 208 and 209, at which contact can be made by a test instrument. In this “M” design embodiment, traces 204, 205 and 206 are aligned in a generally parallel “m” shape, occupying somewhat less space than a similar “T” design, but having a greater stray reactance between them.

Although only a “T” design and an “M” design are show, it should now be evident to the skilled artisan that other shapes and orientations of the plates and traces are possible. Also, other numbers of plates may be used, especially if other numbers of PWB layers are used for matching or compensation components. However, one feature in common among these embodiments is that the capacitive test structure is not connected into a circuit with other components that would complicate the process of measuring the capacitance thereof. As used herein, a circuit may be a complete or partial circuit, or even just a conductive path which becomes part of a circuit when the PWB is placed in service.

Inductive coupling in a compensation circuit is achieved by electromagnetic field coupling between two closely positioned, current-carrying conductors. The distance and orientation between traces on a PWB determines the magnitude and phase of inductive coupling. The traces could be on the same layer or on different layers. As with capacitive structures, PWB manufacturer lot variations include variations affecting the physical relationship between traces. Some of the process variations that occur during manufacturing of the PWB produce variations in trace width, registration between layers, etc.

As shown in FIG. 3, to measure the physical characteristics of the PWB that determine and define inductor parameters, reference lines are added to the PWB to evaluate the PWB fabrication variations. The evaluation could be done by visual inspection, for example, using light transmission through the PWB to locate the traces on different layers or by cross section measurement for more precise value. The evaluation may be useful either in the development process, to determining the manufacturing requirements, or in production, for quality “go/no-go” inspection control.

As mentioned above, according to one aspect of the invention, the inductance test structure is evaluated visually. As shown in FIG. 3, one embodiment of an inductive test structure 300 includes four broken lines of conductive traces 301, 302, 303 and 304 formed on two or more layers of the PWB provide for independent inspection of horizontal and vertical registration errors between the layers. In this exemplary embodiment, lines 301 and 303 are on one layer of a PWB, while lines 302 and 204 are on another layer of the PWB. In the configuration illustrated, the PWB suffers an offset 305 and 306 in each of the x- and y-axis directions, respectively. Other numbers of broken lines, directed in other directions or on other numbers of layers can also be used.

FIG. 4 shows another arrangement for an inductive test structure 400 which can be used. Multi-layer boards can be inspected this way by incorporating one pair of line segments (horizontal 401, 402 and vertical 403, 404) on each layer.

In addition to variation in thickness of the PWB dielectric, which is detected indirectly by measuring the capacitance of the capacitance test structures discussed above, inductive structures are particularly affected by positional offsets. The width 405 of each line of the test structure is designed to indicate when the offset between layers of a PWB exceeds a desired go/no-go limit. That is, in a preferred embodiment, the width of the test structure trace is the maximum allowable mis-registration. Thus, traces on different layers misalign to such an extent that space 406 may be seen between them the PWB should be rejected.

The test structures are added, when possible, directly on the PWB. Alternatively, they may be placed on a test card specially made for the purpose. When PWBs are made in multiple units called panels, test cards can be designed to occupy either unused space on the panel or a space otherwise usable for a PWB. The shape and size of the test structures could be varied to adapt them to the design or information required. Use of appropriate test structures allows evaluation of various suppliers and production lots. Thus, these test structures are a nice tool to understand and control PWB variations and consequently to improve the compensation designed into PWBs used to connect RJ-45 style or other standard connectors to other connector types, such as IDCs.

How much manufacturing variation in the PWBs for a particular application, for example in the connector compensation application disclosed in U.S. Pat. No. 5,326,284 incorporated herein by reference, can be tolerated may be determined empirically. By measuring a large number of PWBs having variations in thickness and registration between layers in actual use, dimensions of the test structures and the go/no-go criteria can be set. The precise dimensions and criteria arrived at will depend on the circuit which is desired to be implemented using the PWB traces. Once go/no-go limits have been established by measuring large numbers of samples and comparing the measured results to actual performance of the finished PWBs during the design phase, ordinary lot-testing, sampling techniques are used in manufacturing.

The present invention has now been described in connection with a number of specific embodiments thereof. However, numerous modifications, which are contemplated as falling within the scope of the present invention, should now be apparent to those skilled in the art. Therefore, it is intended that the scope of the present invention be limited only by the scope of the claims appended hereto.

What is claimed is:

1. A test structure for a printed wiring board (PWB), comprising at least one of:
a plurality of conductive traces disposed on separate layers of the PWB and superposed to form a capacitor, separate from any circuit formed on the PWB, and
a plurality of conductive traces dissposed on separate layers of the PWB which are aligned when the separate layers of the PWB are properly aligned.

2. A method of testing a printing wiring board (PWB), comprising steps of:
measuring capacitance of a capacitor formed by traces on the PWB, the capacitor independent of any circuit on the PWB; and
comparing visual alignment of plural traces discrete from any circuit on the PWB to an acceptance criteria.

3. In a printed wiring board (PWB), including at least one substantially reactive circuit element formed of conductive traces on plural layers thereof, a test structure comprising at least one of:
a capacitor including conductive traces on plural layers thereof the capacitor independent of any circuit on the PWB; and
an inductive test structure including conductive traces on plural layers thereof whole alignment is detectable optically by an unaided observer.
